(19) United States
(12) Patent Application Publication
(10) Pub. No.: US 2019/0301012 A1
(43) Pub. Date: Oct. 3, 2019

(54) WAFER PROCESSING SYSTEM WITH FLOW EXTENDER

(71) Applicant: VEECO INSTRUMENTS INC., Plainview, NJ (US)

(72) Inventors: Aniruddha BAGCHI, Plainview, NY (US); Bojan MITROVIC, Plainview, NY (US); Changhung Paul CHANG, Plainview, NY (US); Alexander GURARY, Plainview, NY (US)

(21) Appl. No.: 16/353,855

(22) Filed: Mar. 14, 2019

Related U.S. Application Data
(60) Provisional application No. 62/651,492, filed on Apr. 2, 2018.

(51) Int. Cl. C23C 16/455; C23C 16/458; H01L 21/67; H01L 21/687

(52) U.S. Cl. CPC C23C 16/455; C23C 16/4584; H01L 21/68771; H01L 21/68764; H01L 21/67017

(57) ABSTRACT

Wafer processing systems and ring flow extenders used in those systems, the flow extender being proximate and around the peripheral edge of the wafer carrier. The ring flow extender has a top surface facing in the upstream direction, the ring being constructed and arranged so that when the reactor is in an operative condition, the ring closely surrounds the wafer carrier and the top surface of the ring is substantially planar and/or continuous with the top surface of the carrier. The ring flow extender has an outer peripheral surface that includes a radiused portion at or proximate to the top surface of the ring.

### CROSS REFERENCE

The present application claims priority to U.S. provisional application 62/651,492 filed Apr. 2, 2018, the entire disclosure of which is incorporated herein by reference for all purposes.

### BACKGROUND

Many semiconductor devices are formed by processes performed on a substrate that is commonly referred to as a “wafer.” Typically, the wafer is formed from a crystalline material and is in the form of a disc. Devices formed from compound semiconductors, such as III-V semiconductors, typically are formed by growing successive layers of the compound semiconductor on the wafer using metal organic chemical vapor deposition or “MOCVD.” In such a process, the wafer is exposed to a combination of gases that flow over the surface of the wafer while the wafer is maintained at an elevated temperature. One example of a III-V semiconductor is gallium nitride, which can be formed by reaction of an organo gallium compound and ammonia on a substrate having a suitable crystal lattice spacing, as, e.g., a sapphire wafer.

Composite devices can be fabricated by depositing numerous layers in succession on the surface of the wafer under slightly different reaction conditions. For example, for a gallium nitride based semiconductor, indium, aluminum or both can be used in varying proportion to vary the bandgap of the semiconductor. Also, p-type or n-type dopants can be added to control the conductivity of each layer. After all of the semiconductor layers have been formed and, typically, after appropriate electric contacts have been applied, the wafer is cut into individual devices. Devices such as light-emitting diodes (“LEDs”), lasers, and other optoelectronic devices can be fabricated in this way.

In a typical chemical vapor deposition (CVD) process, numerous wafers are held on a device commonly referred to as a wafer carrier so that a top surface of each wafer is exposed at the top surface of the wafer carrier. The wafer carrier is then placed into a reaction chamber and maintained at the desired temperature while the gas (e.g., gas mixture) flows over the surface of the wafer carrier. It is important to maintain uniform conditions (temperature and gas concentrations) at all points on the top surfaces of the various wafers on the carrier during the process. Variations in process conditions can cause undesired variations in the properties of the resulting semiconductor device. For example, variations in the rate of deposition can cause variations in thickness of the deposited layers, which in turn can lead to non-uniform characteristics in the resulting devices. Thus, considerable effort has been devoted in the art heretofore towards maintaining uniform conditions.

One type of CVD apparatus which has been widely accepted in the industry uses a wafer carrier in the form of a large disc with numerous wafer-holding regions, each region adapted to hold one wafer. While the carrier is rotated, reactive gas is directed downwardly onto the top surface of the wafer carrier; the gas flows across the top surface toward the periphery of the wafer carrier. The outwardly-flowing gas forms a boundary layer covering the top surface of the wafer carrier. The used gas flows downwardly around the periphery of the wafer carrier and is evacuated from the reaction chamber through ports below the wafer carrier.

The rate of certain treatment processes, such as the growth rate in an MOCVD process under mass-transport-limited growth conditions, is inversely related to the boundary layer thickness. A thin and uniform diffusion boundary layer is desirable to achieve uniform and fast deposition rate during the MOCVD epitaxial growth. Typically, with stable flow conditions in the reactor and with substantially uniform heating of the wafer carrier, uniform boundary layer thickness can be achieved for the majority of the wafer carrier surface. However, near the periphery of the wafer carrier, the gas flow begins to change direction from radial above the wafer carrier to the downward flow which carries the gas from the wafer carrier to the exhaust. In the edge region of the wafer carrier near the periphery, the boundary layer becomes thinner and hence the process rate increases appreciably. For example, if a wafer is positioned on the carrier with a portion of the wafer proximate the edge region where the boundary layer is thinner, the CVD process will form layers of uneven thickness on that wafer; thicker portions will be formed on those parts of the wafer disposed in the edge region.

To avoid this problem, wafers are typically not positioned in the edge region. Thus, the pockets, regions, or other wafer-holding features of wafer carriers typically are provided only in the area of the wafer carrier remote from the periphery. This limits the number and size of wafers which can be accommodated on a carrier of a given size, and therefore limits the productivity of the equipment and process.

Thus, although considerable effort has been devoted in the art heretofore to design and optimize such systems, still further improvement would be desirable.

### SUMMARY

The present disclosure is directed to wafer processing systems and to flow extenders used in those systems, the flow extender being proximate the peripheral edge of the wafer carrier. In particular, the systems have a chamber with a wafer carrier therein and a ring flow extender around the carrier. The ring flow extender has a top surface facing in the upstream direction, the ring being constructed and arranged so that when the reactor is in an operative condition, the ring closely surrounds the wafer carrier and the top surface of the ring is substantially continuous with the top surface of the carrier. The ring flow extender has an outer peripheral surface that includes a radiused portion at or proximate to the top surface of the ring.

In one particular implementation, this disclosure provides a ring flow extender for a wafer processing system. The ring flow extender has a top surface, a bottom surface opposite the top surface, an inner surface and an outer peripheral surface having a radiused portion proximate the top surface and a lower portion proximate the bottom surface, the radiused portion defined by a radius no greater than 0.5 inch and extending from the top surface no more than 0.5 inch. In some implementations, the ring flow extender has the radiused portion defined by a radius no greater than 0.4 inch and extending from the top surface no more than 0.4 inch.

In another particular implementation, this disclosure provides a wafer processing system, the system having a chamber with a ring flow extender within the chamber. The chamber has a wall defining an interior volume, with a wafer carrier in the chamber, the wafer carrier having a peripheral edge and a top surface, and configured to retain at least one wafer. The ring flow extender has a top surface, a bottom surface opposite the top surface, an inner surface and an outer peripheral surface facing away from the wafer carrier extending from the top surface to the bottom surface, the outer peripheral having a radiused portion proximate the top surface defined by a radius no greater than 0.5 inch. The radiused portion may extend along the outer peripheral surface from the top surface no more than 1 inch, no more than 0.5 inch, or no more than 0.4 inch.

In yet another particular implementation, this disclosure provides a method for processing at least one wafer. The method includes positioning a wafer carrier supporting at least one wafer in a top surface thereof and a ring flow extender inside a reaction chamber, with the ring surrounding the wafer carrier with a top surface of the carrier and a top surface of the ring facing in an upstream direction and being substantially planar with one another, the ring having an outer peripheral surface facing away from the wafer carrier, the outer peripheral surface having a radiused portion proximate the top surface of the ring defined by a radius no greater than 0.5 inch. The method further includes directing one or more treatment gases in a downstream direction opposite to the upstream direction onto the top surface of the carrier and the at least one wafer while rotating the carrier and the at least one wafer around an upstream-to-downstream axis of the carrier, so that treatment gases flow outwardly over the top surface of the carrier and over the top surface of the ring.

In some implementations, the method further includes exhausting the one or more treatment gases from the chamber downstream of the ring flow extender so that the gases flowing outwardly over the top surface of the ring pass downstream within a gap between the outer peripheral surface of the ring and a wall of the reaction chamber. Additionally or alternately, the method includes moving the ring upstream or downstream after the directing step, and optionally moving a shutter mechanically connected to the ring from an operative position to an open position in which the shutter does not occlude an opening in the chamber wall.

This Summary is provided to introduce a selection of concepts in a simplified form that are further described below in the Detailed Description. This Summary is not intended to identify key or essential features of the claimed subject matter, nor is it intended to be used to limit the scope of the claimed subject matter. These and various other features and advantages will be apparent from a reading of the following Detailed Description.

### BRIEF DESCRIPTION OF THE DRAWING

FIG. 1 is a schematic cross-sectional side view of an example wafer processing system having a generic ring flow extender.

FIG. 2 is an enlarged view of the region indicated at “2” in FIG. 1 showing the generic ring flow extender.

FIG. 3A is a schematic side view of a first example of a ring flow extender according to the disclosure shown proximate a wafer carrier; FIG. 3B is a schematic side view of a second example of a ring flow extender according to the disclosure, and FIG. 3C is a schematic side view of a third example of a ring flow extender according to the disclosure.

FIG. 4A is a schematic side view of a fourth example of a ring flow extender according to the disclosure; FIG. 4B is a schematic side view of a fifth example of a ring flow extender according to the disclosure, and FIG. 4C is a schematic side view of a sixth example of a ring flow extender according to the disclosure.

FIGS. 5A, 5B and 5C are modeled aerodynamic figures showing the air currents around the ring flow extenders of FIGS. 4A, 4B and 4C, respectively.

FIG. 6 is a graphical representation of the normalized rate of deposition across a carrier.

FIG. 7 is an enlarged graphical representation of the normalized rate of deposition across a carrier in relation to various wafer arrangements on that carrier.

### DETAILED DESCRIPTION

This disclosure is directed to ring flow extenders for increasing the effective surface area of a wafer carrier in a wafer processing system. The ring flow extenders of this disclosure have a profile including a radiused portion proximate the carrier top surface that inhibits recirculation of air currents (e.g., eddies) on or at the outer peripheral surface of the ring which thus inhibits particulate accumulation.

The following description provides specific implementations. It is to be understood that other implementations are contemplated and may be made without departing from the scope or spirit of the present disclosure. The following detailed description, therefore, is not to be taken in a limiting sense. While the present disclosure is not so limited, an appreciation of various aspects of the disclosure will be gained through a discussion of the examples provided below.

In the following description, reference is made to the accompanying drawing that forms a part hereof and in which are shown by way of illustration at least one specific implementation. In the drawing, like reference numerals may be used throughout several figures to refer to similar components.

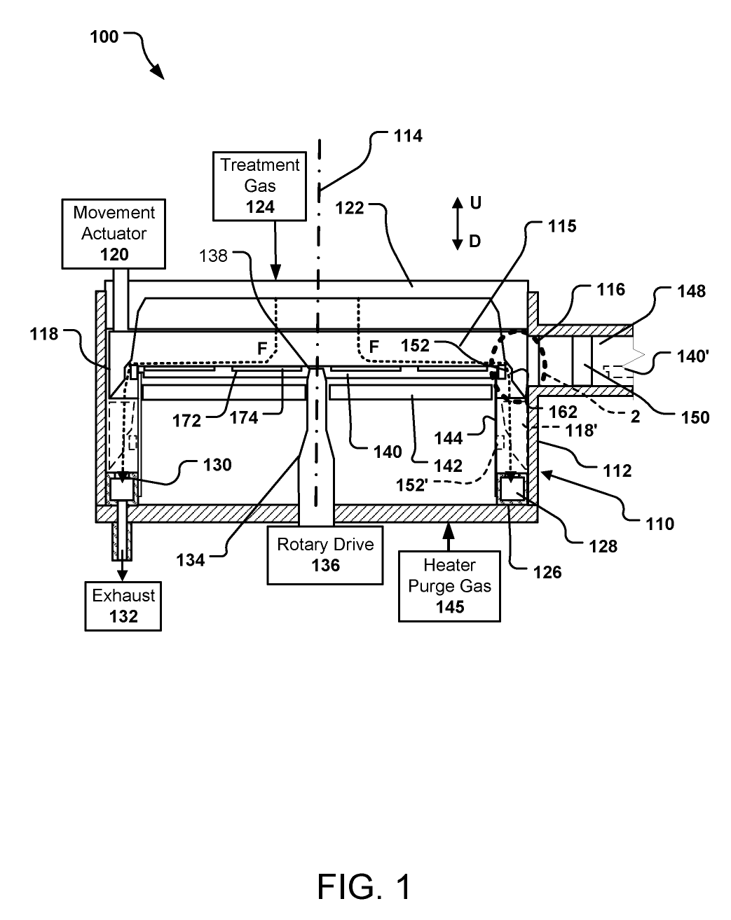

Seen in FIG. 1, a wafer processing system 100 has a reaction chamber 110 having a wall structure which incorporates a fixed wall 112 defining a generally cylindrical interior space 115 having a central axis 114 and an opening 116 in the wall 112 communicating with the interior space 115. As further discussed below, gas flow within the reaction chamber 110 during operation is generally from the region at the top of the drawing in FIG. 1 toward the region at the bottom of the drawing. Therefore, the direction along the axis toward the bottom of the drawing, indicated by arrow D in FIG. 1, is referred to herein as the “downstream” direction, and the opposite direction denoted by arrow U is referred to herein as the “upstream” direction.

The wall 112 of the chamber 110 further includes a ring-like shutter 118 that has a central axis coincident with the central axis 114. The shutter 118 is mounted for movement in the upstream and downstream directions relative to the fixed wall 112 and is connected to a movement actuator 120. The actuator 120 is arranged to move the shutter 118 between the operative position illustrated in solid lines in FIG. 1 and the open position depicted in broken lines as 118′ in FIG. 1. When the shutter 118 is in the operative position, it covers the opening 116 inhibiting flow through the opening 116. Typically, the shutter 118 does not form a gas-tight seal at the opening 116. The fixed wall 112 and the shutter 118 may be provided with coolant passages (not shown) inside the walls or on their exterior surfaces so that the wall 112 and the shutter 118 can be maintained at desired temperatures during operation of the system 100. Such coolant passages could be connected to a coolant supply apparatus.

A gas inlet element 122 is provided at an upstream end of the chamber 110, towards the top of the drawing in FIG. 1. The gas inlet element 122 is connected to one or more gas sources 124 arranged to supply one or more treatment gases; if multiple treatment gases are used, the gases may be sourced as a mix or may be sourced individually. The gas inlet element 122 may be generally conventional and may be arranged to discharge the treatment gases into the chamber 110 in a flow directed generally in the downstream direction D, e.g., utilizing a pattern of discharges spaced around the central axis 114 and distributed at various radial distances from the central axis 114. The gas inlet element 122 can also be provided with coolant channels (not shown) for maintaining its temperature during the process.

A hollow hoop-like exhaust manifold 126 is provided at the downstream end of the chamber 110. The exhaust manifold 126 has an interior passage 128 and numerous ports 130 open to the interior space 115 of the chamber 110. The interior passage 128 of the exhaust manifold 126, in turn, is connected to an exhaust system 132 arranged to pump gases out of the interior space 115 and discharge the gases to waste.

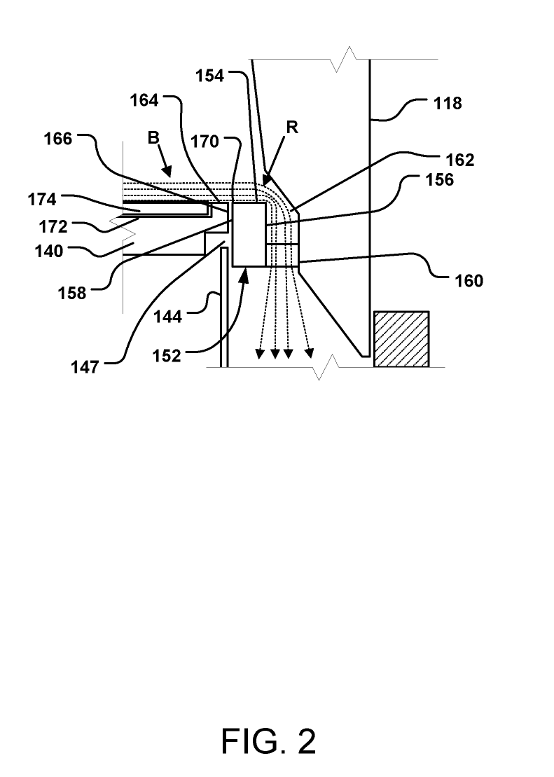

A spindle 134, connected to a rotary drive mechanism 136, is mounted to the fixed wall structure 112 for rotation about the central axis 114. The spindle 134 has a fitting 138 at its upstream end to releasably engage and hold a wafer carrier 140 at the carrier location depicted in FIG. 1. The carrier location is downstream from the gas inlet element 122, but upstream from the exhaust manifold 126. A heater 142 is positioned downstream from the carrier location and surrounds spindle 134. The heater 142 can be supported within the chamber 110 by supports (not shown) fixed to the fixed wall structure 112. A circular baffle 144 surrounds the heater 142 and extends downstream from the heater 142 and the carrier location. A heater purge gas source 145 communicates with the space inside the baffle 144. As best seen in FIG. 2, the baffle 144 is dimensioned so that, when the wafer carrier 140 is mounted at the carrier location, there is a small gap 147 between the baffle 144 and the carrier 140. During operation, the heater purge gas source 145 feeds a purge gas, such as nitrogen, into the space within the baffle 144 so that the purge gas flows out of this space through the gap 147 and passes to the exhaust system 132 along with the other gas flows discussed below. The heater purge gas prevents the treatment gas from contacting and attacking the heater 142.

An antechamber 148 communicates with the opening 116 in the fixed wall 112. The antechamber 148 is provided with a closure, such as a gate valve element 150, schematically shown in FIG. 1. The gate valve element 150 is arranged to seal the antechamber 148 and thus block communication between the antechamber 148 and the interior space 115. The valve element 150 can be moved to a retracted position (not shown) to allow communication between the antechamber 148 and the interior space 115. When the valve element 150 is in the retracted position and the shutter 118 is in the open position 118′, the wafer carrier 140 can be removed from its engagement with the fitting 138 of the spindle 134 and moved through the opening 116 into the antechamber 148, e.g., using a robotic handling apparatus (not shown). A new wafer carrier 140′ can be moved from the antechamber 148 into the reaction chamber 110 and engaged with the fitting 138 so that the new wafer carrier 140′ is positioned at the carrier location.

A ring 152 is positioned within the interior space 115 of the chamber 110 and mounted in relation to the shutter 118. As best seen in FIG. 2, the ring 152 has a top surface 154 facing in the upstream direction, an outer peripheral surface 156 facing radially outwardly away from the central axis, and an inner surface 158 facing radially inwardly, toward the central axis 114. The ring 152 is mounted to the shutter 118 by struts 160 present around the circumference of the chamber 110. One such strut is depicted in FIG. 2 as 160 positioned below the top surface 154 of the ring 152. The outer peripheral surface 156 of the ring 152 is radially spaced inward from the adjacent surface of the shutter 118, so that a gap 162 exists between the surface of the shutter 118 and the ring 152, particularly the outer peripheral surface 156 of the ring 152. For example, in a system 100 arranged to hold a 465 mm diameter wafer carrier, the width of the gap 162, at its narrowest point, may be about 13 mm. Because the struts 160 are relatively thin, they do not materially obstruct (downward) airflow or other flow through gap 162.

The dimensions of the ring 152 and its mounting to shutter 118 are selected so that when the shutter 118 is in an operative condition, as shown in solid lines in FIG. 1 and as depicted in FIG. 2, and when the wafer carrier 140 is in an operative condition and positioned at the carrier location in engagement with the fitting 138 on the spindle 134, the top surface 154 of the ring 152 is level, e.g., coplanar, or substantially level, e.g., substantially coplanar, with the top or upstream surface 164 of the carrier 140. The width or radial extent of the ring 152 may be about 5-20 mm, in other implementations about 10-15 mm or 13-15 mm, although in some implementations greater ring widths are more desirable. Where the ring 152 is to be fitted into existing systems originally built without the ring, the ring width is limited by the need to provide a gap 162 of sufficient width.

The ring 152 is dimensioned and mounted so that, in the operative condition, the inner surface 158 of the ring 152 lies adjacent the exterior peripheral surface 166 of the wafer carrier 140, leaving only a small gap 170 between the surfaces 158, 166. Desirably, the gap 170 is as small as practicable, consistent with manufacturing tolerances and allowances for differential thermal expansion of the components. For example, the gap 170 may be about 3 mm wide, about 2 mm wide or less.

Each wafer carrier 140 defines numerous pockets 172 in the top surface 164 of the carrier 140, each of which is arranged to hold a wafer 174 so that a top surface of the wafer 174 is (substantially) aligned or coplanar with the top surface 164 of the carrier 140. In some implementations, the wafer carrier 140 has a relatively sharp edge or corner at the juncture of its top surface 164 and its peripheral surface 166, and the ring 152 desirably also has sharp edges or corners at the juncture of its top surface 154 with the inner surface 158 and the exterior peripheral surface 156. These sharp edges desirably are defined by radii less than about 0.1 mm. In other implementations, either or both the wafer carrier 140 and the ring 152 have rounded or tapering corners.

In operation, the system 100 is brought to its operative condition (as shown in FIGS. 1 and 2) with the wafer carrier 140 (optionally bearing wafers 174) positioned on the spindle 134 and with the shutter 118 in the operative position shown in solid lines, so that the ring 152 closely surrounds the peripheral surface of the carrier 140. The heater 142 is actuated to bring the wafer carrier 140 and wafers 174 to the desired temperature, and the gas inlet element 122 is actuated to discharge treatment gases, while the rotary drive 136 is actuated to spin the spindle 134 and the wafer carrier 140 about the central axis 114. The gas discharged by the gas inlet element 122 passes generally as indicated by flow arrows F in FIG. 1. Thus, the gas passes downstream from the inlet element 122 towards the carrier location and flows generally radially outwardly over the top surface 164 of the carrier 140 and the wafers 174 retained therein or thereon. The flowing gas passes outwardly beyond the periphery of the wafer carrier 140 and over the ring 152, and then passes downwardly through the gap 162 between the ring 152 and the wall surface defined by the shutter 118. Although a minor amount of the gas may pass downwardly through the smaller gap 170 (FIG. 2), this minor amount does not substantially influence the flow dynamics of the system. The gas continues downstream towards the exhaust manifold 126, passes through the exhaust ports 130, and into the interior exhaust passage 128 and out from the system 100 through the exhaust system 132.

As best seen in FIG. 2, the gas flowing outwardly over the top surface 164 of the wafer carrier 140 and over the surfaces of the wafers 174 forms a boundary layer B having a thickness. Within this boundary layer B, the gas flow streamlines are nearly parallel to the top surface 164 of the carrier 140, so that the boundary layer B has a substantially uniform thickness. However, as the gas approaches the gap 162, the streamlines converge appreciably in a region R, and the thickness of the boundary layer B decreases appreciably within this region R. Any parts of wafers 174 that are positioned within the region R are subject to uneven growth rates due to the decreased thickness of the boundary layer B.

However, in the view depicted in FIG. 2, this region R is positioned over the ring 152 and not over the wafer carrier 140. Therefore, the boundary layer maintains a substantially uniform thickness over substantially the entire top surface 164 of the wafer carrier 140. This provides a substantially even reaction rate over surfaces of all the wafers 174, even when the wafers 174 are positioned immediately adjacent to or close to the peripheral surface 166 of the carrier 140. In such a manner, the ring 152 is a flow extender, extending the gas flow across the carrier 140. The presence of the ring 152 allows placement of the wafer carrier pockets or regions closer to the periphery of the carrier 140 than if no ring was present. Thus, the ring 152 increases the capacity of the carrier 140. This, in turn, increases the throughput of the system 100, i.e., the number of wafers which can be processed per unit time.

Moreover, placing wafers 174 closer to the periphery of the carrier 140 promotes efficient use of the treatment gases. These gases typically are expensive, high-purity materials. Typically, the amount of each gas is determined to provide a constant amount per unit area over the entire area of the wafer carrier. By placing wafers closer to the periphery of the carrier, more of the area of the carrier can be covered by wafers, and more of the gas will be used to treat wafers.

FIGS. 1 and 2 and the discussion above have provided a general overview of a wafer processing system 100 that utilizes a ring flow extender proximate the wafer carrier to increase the area of the substantially uniform thickness boundary layer. The following figures and discussion are directed to various different embodiments of the ring flow extender.

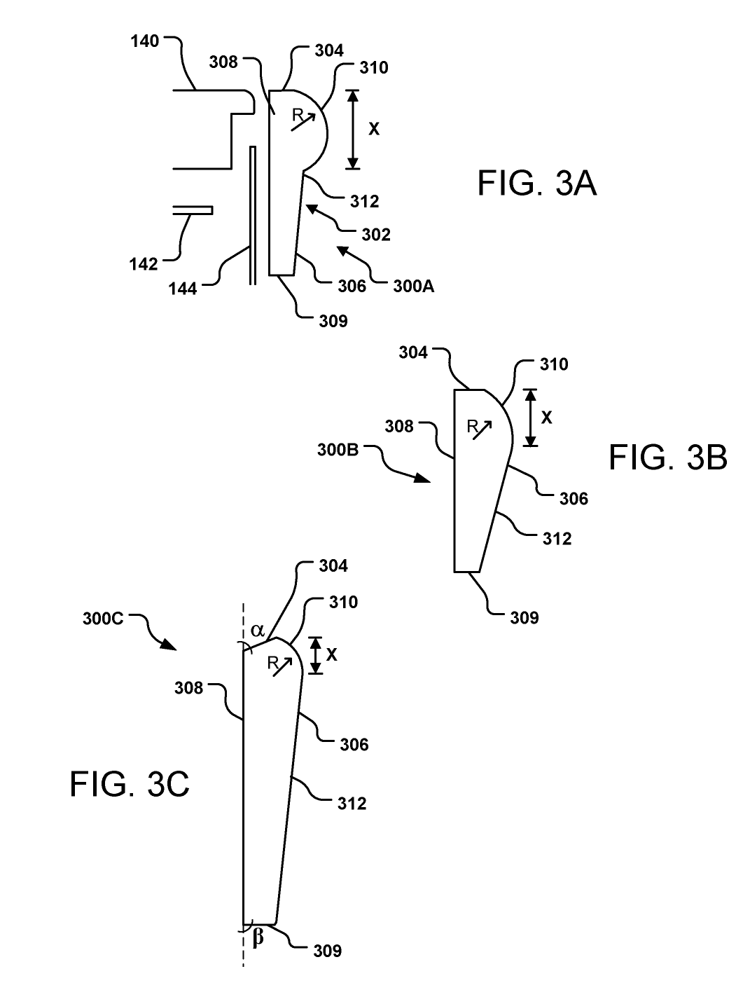

Turning to FIG. 3A, a ring flow extender 300A is shown in cross-sectional side view proximate a wafer carrier 140. Also shown in FIG. 3A are the heater 142 and the baffle 144.

The ring flow extender 300A has a body 302 with a top surface 304 facing in the upstream direction (when the ring 300A is positioned in the wafer processing system 100), an outer peripheral surface 306 facing radially outwardly away from the central axis (when the ring 300A is positioned in the wafer processing system 100), and an inner surface 308 facing radially inwardly, toward the central axis (when the ring 300A is positioned in the wafer processing system 100). The ring 300A also has a bottom surface 309 opposite the top surface 304. The outer peripheral surface 306 has an upper radiused portion 310 and a lower portion 312 that meet at an evident juncture point, with the radiused portion 310 defined by a radius R and extending a distance x from the top surface 304. The width of the ring 300A (from the inner surface 308 to the outer surface 306) has a generally tapering shape from the top surface 304 to the bottom surface 309 due to the generally angled nature of the outer peripheral surface 306. In the implementation of FIG. 3A, the top surface 304 is substantially level, e.g., planar or coplanar, with the top or upstream surface of the carrier 140.

FIG. 3B shows an alternate ring flow extender 300B, having features similar to the ring 300A. The implementation of FIG. 3B has a top surface 304 that is substantially level, e.g., planar or coplanar, with the top or upstream surface of the carrier 140, however the radiused portion 310 and the lower portion 312 have a smooth transition or juncture. In FIG. 3B, the ring flow extender 300B has a top surface 304, an outer peripheral surface with an upper radiused portion 310 and a lower portion 312, an inner surface 308 and a bottom surface 309. The radiused portion 310 is defined by a radius R and extends a distance x from the top surface 304. The lower portion 312 angles as it extends from the radiused portion 310 to the bottom surface 309 so that the ring 300B has a tapering shape.

Another implementation of a ring flow extender is in FIG. 3C as ring 300C. Similar to the rings 300A and 300B, the ring 300C has a top surface 304, an outer peripheral surface 306 with an upper radiused portion 310 and a lower portion 312, an inner surface 308 and a bottom surface 309 opposite the top surface 304. The radiused portion 310 is defined by a radius R and extends a distance x from the topmost portion of the top surface 304. The lower portion 312 has a smooth transition from the radiused portion 310 and it tapers as it extends from the radiused portion 310 to the bottom surface 309.

For the ring 300C, however, the top surface 304 is at an angle α measured from vertical, or, “α+90 degrees” to the horizontal top or upstream surface of the carrier, sloping upward away from the carrier. Additionally, the bottom surface 309 can be at an angle, measured as angle β from vertical. FIG. 3C shows the angle β as 90 degrees, or, horizontal, although in other implementations the bottom surface 309 may slope upward or downward away from the carrier. For example, angle β may be, 20 to 70 degrees, e.g., 30 to 60 degrees.

For implementations of rings having a sloped top surface, such as in the ring 300C, when installed in a system such as the system 100, the edge or corner of the ring closest to the wafer carrier 140, which is the corner formed by the inner surface 308 and the top surface 304, is level or planar with, or substantially level or planar with, the top surface 164 of the wafer carrier 140.

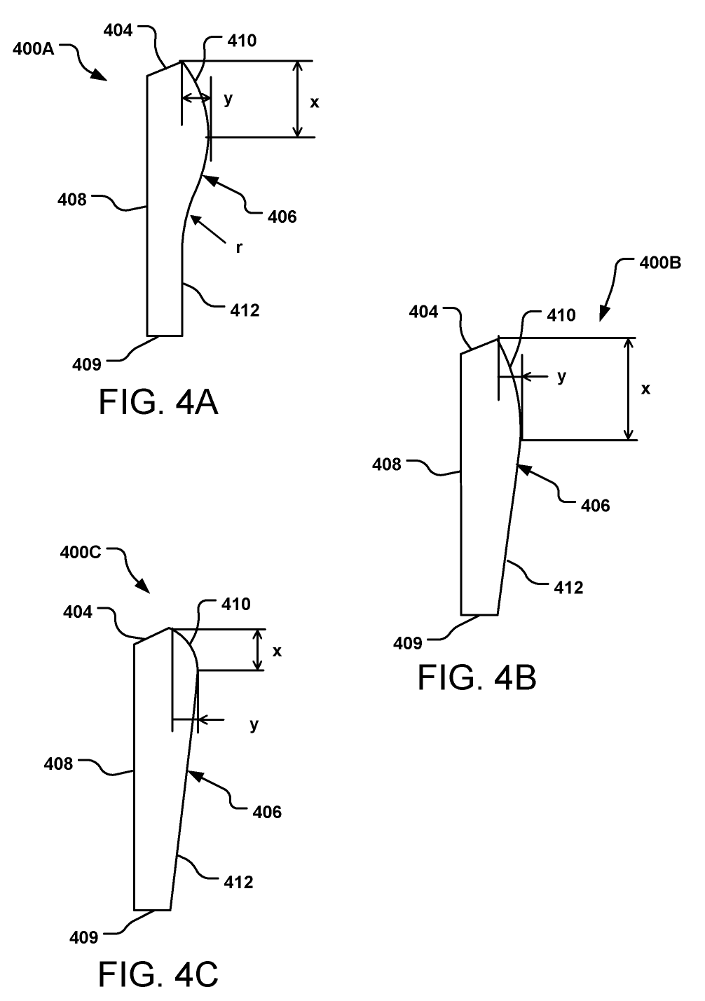

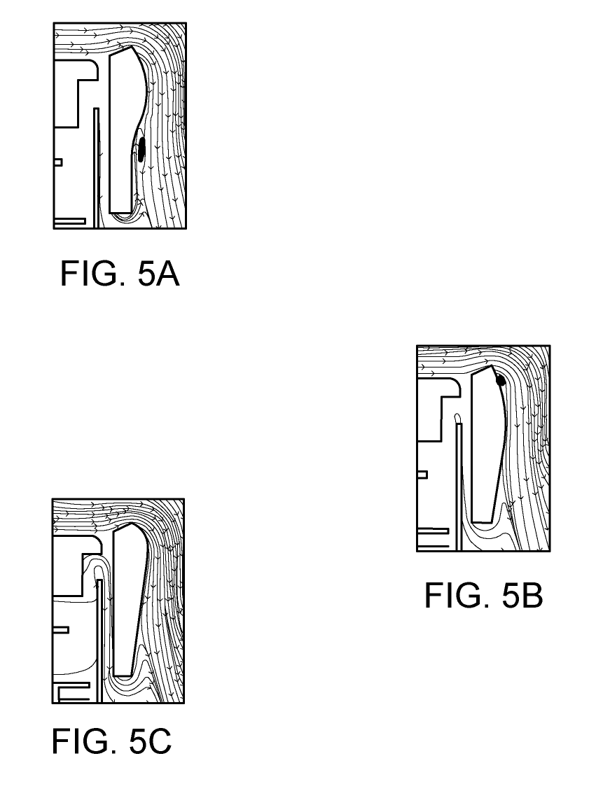

FIGS. 4A, 4B and 4C show additional implementations of ring flow extenders and FIGS. 5A, 5B and 5C, respectively, show design modeling of air flow currents over and around the ring and locations of resulting potential particulate accumulation.

Turning to FIG. 4A, a ring 400A has an angled top surface 404, an outer peripheral surface 406 with an upper radiused portion 410 and a lower portion 412, an inner surface 408 and a bottom surface 409. Unlike the rings shown in FIGS. 3A, 3B and 3C, the ring 400A has a lower portion 412 that includes a concave transition between the upper radiused portion 410, the concave transition defined by a radius r, e.g., ranging from about 0.05 to about 0.35 inch, rather than having a straight tapering transition from the radiused portion 410 to the lower portion 412. The radiused portion 410 extends a distance x from the topmost portion of the top surface 404 and extends past the corner of the top surface 404 and/or the corner of the bottom surface 409 a distance y. The distance x may be, e.g., about 0.1 to about 0.5 or 0.4 inch, and the distance y may be, e.g., about 0.05 to about 0.3 inch.

FIG. 5A shows the airflow over and around the ring 400A. As seen in FIG. 5A, the ring is positioned with the corner formed by the inner surface and the top surface level or planar with, or substantially level or planar with, the top surface of the wafer carrier. The modeling shows that an area of recirculation occurs proximate the concave area in the lower portion 412; this area of recirculation increases the probability of accumulating particulate.

Similar to the ring 400A, a ring 400B in FIG. 4B has an angled top surface 404, an outer peripheral surface 406 with an upper radiused portion 410 and a lower portion 412, an inner surface 408 and a bottom surface 409 with the lower portion 412 tapering toward the bottom surface 409. The ring 400B has a smooth transition from the radiused portion 410 to the lower portion 412 without the concave feature of the ring 400A. The radiused portion 410 extends a distance x from the topmost portion of the top surface 404 and extends past the corner of the top surface 404 and/or the corner of the bottom surface 409 a distance y. The distance x may be, e.g., about 0.3 to about 0.7 inch, and the distance y may be, e.g., about 0.05 to about 0.2 inch.

FIG. 5B shows the airflow over and around the ring 400B. The modeling shows that an area of recirculation occurs in the radiused portion proximate the top surface 404; this area of recirculation increases the probability of accumulating particulate.

Similar to the ring 400B of FIG. 4B, a ring 400C in FIG. 4C has an angled top surface 404, an outer peripheral surface 406 with an upper radiused portion 410 and a lower portion 412, an inner surface 408 and a bottom surface 409. The radiused portion 410 extends a distance x from the topmost portion of the top surface 404 and extends past the corner of the top surface 404 and/or the corner of the bottom surface 409 a distance y. For this ring 400C, the distance x may be, e.g., about 0.1 to about 0.5 or 0.4 inch, and the distance y may be, e.g., about 0.05 to about 0.25 inch.

FIG. 5C shows the airflow over and around the ring 400C. The modeling shows no prominent area of recirculation.

Thus, various cross-sectional profiles of ring flow extenders have been described and shown. Each ring flow extender has a top surface, an outer peripheral surface with an upper radiused portion and a lower portion, an inner surface and a bottom surface. The ring flow extender has an overall width and an overall length or height.

The top surface may have an angle α, when measured from the inner surface of the ring, of 45 to 90 degrees (90 degrees being horizontal), in other implementations 60 to 75 degrees, sloping upward away from the carrier. The bottom surface may be horizontal or have may have an angle β, e.g., 20 to 70 degrees, e.g., 30 to 60 degrees.

The upper radiused portion may have a fairly ‘sharp’ curvature, in some implementations, defined by a radius of 0.1 to 0.5 inches (about 2.5 to about 12.5 mm), in other implementations 0.2 to 0.4 inches (about 5 to about 10 mm). The upper radiused portion may extend a distance (measured from the topmost of the top surface of the ring) 0.1 to 1 inch (about 2.5 to about 25 mm), in other implementations 0.1 to 0.5 inches (about 2.5 to about 12.5 mm). Specific examples of lengths of the upper radiused portion for the rings 400A, 400B and 400C are provided above. Additionally or alternately, the upper radiused portion may extend a distance (measured from the top of the top surface of the ring) that is, e.g., no more than 20% of the overall length of the outer peripheral surface, such as 5 to 20% of the overall length, in other implementations 10% to 15%.

The lower portion of the outer peripheral surface may be linear or include a concave or convex curve; any curve may be the entire length of the lower portion or a portion of the lower portion. The lower portion provides an overall tapered shape to the ring from the top surface to the bottom surface.

When the ring flow extender is operably installed in a system with a wafer carrier, the top surface may be essentially aligned with, coplanar with, or otherwise even with the top of the carrier, or may be angled in respect to the carrier, either away from or toward the carrier. When installed in a system with a wafer carrier, the corner where the inner surface and the top surface meet may be essentially aligned with, coplanar with, or otherwise even with the top surface of the carrier.

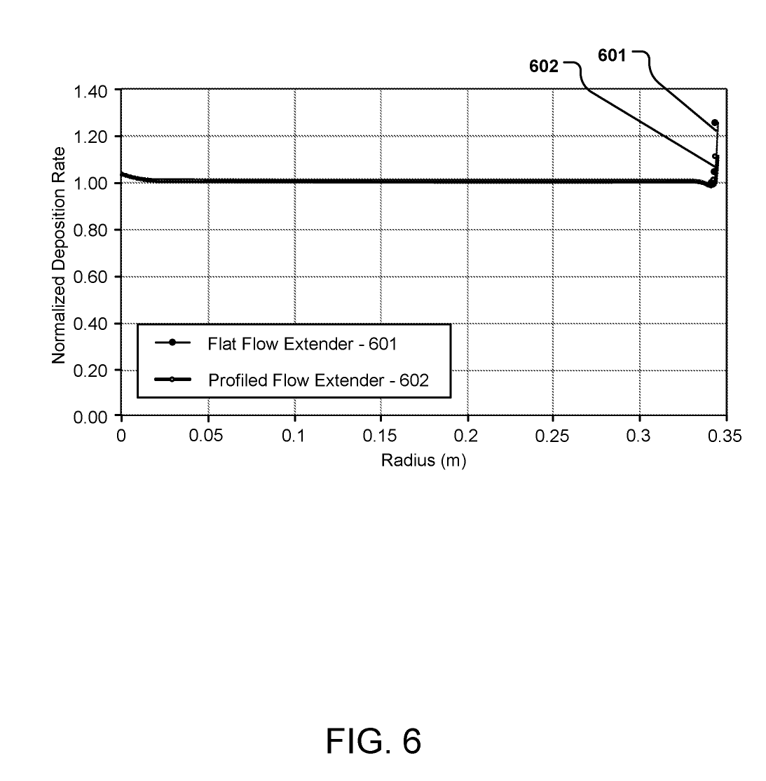

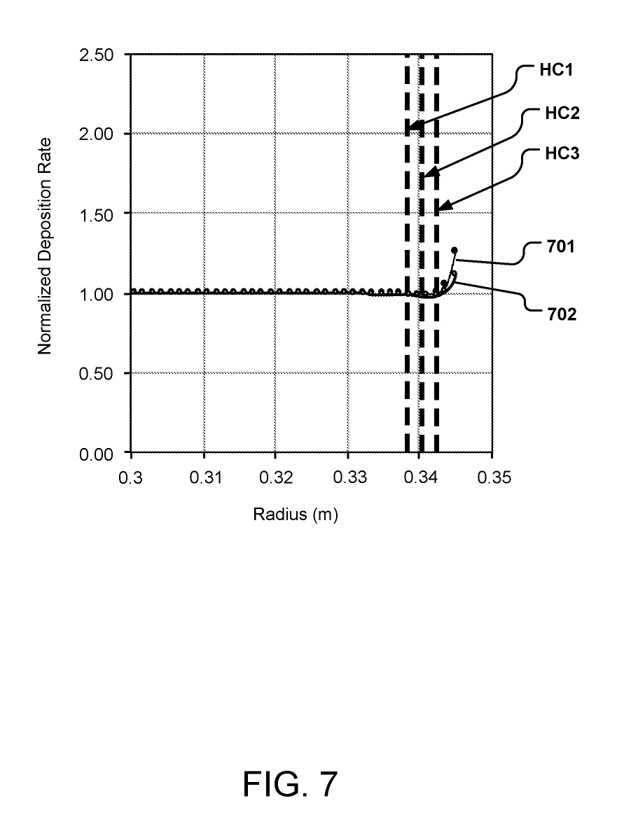

FIGS. 6 and 7 graphically illustrate the benefit of having a ring flow extender having a radiused portion proximate the top surface over one without a radiused portion. FIG. 7 is a portion of FIG. 6 enlarged to show the details. For these figures, the “Profiled Flow Extender” has the profile as illustrated in FIG. 3C with a radiused portion on its outer peripheral surface, whereas the “Flat Flow Extender” has a flat profile on its outer peripheral surface, without a radiused portion and overall tapering shape. The ring flow extenders were installed in system around a wafer carrier.

In both FIG. 6 and FIG. 7, the graphs show the normalized deposition rate across the wafer carrier, from the center of the carrier (at radius=0) toward the edge of the carrier and the adjacent flow extender positioned around the carrier. The figures show that the flat flow extender, designated by curves 601 and 701 had a greater increase in deposition rate at the periphery of the carrier than did the profiled flow extender, designated by curves 602 and 702. The large spike in curve 601 is undesirable, as it produced an uneven deposition on the wafers proximate that location. FIG. 7 includes lines (HC1, HC2, HC3) representing the periphery of the outermost wafer on the carrier for arrangements for a variety of high capacity wafer carriers supporting 4 inch wafers; HC3 had more wafers on the carrier than HC2 which has more wafers than HC1. Although both ring flow extenders had a generally even deposition rate for all of the wafer arrangements, the profiled flow extender (having an upper radiused portion) decreased the potential for a large deposition rate change proximate the periphery and hence, decreased uneven deposition and thus unsuitable wafers.

Thus, as can be seen in FIGS. 6 and 7, a profiled ring flow extender (having an upper radiused portion) results in better growth uniformity at the wafer carrier periphery compared to a flat flow extender without a radiused portion on its outer peripheral surface. With a profiled ring flow extender, uniform conditions can be maintained at all points on the top surfaces of the various wafers on the wafer carrier more readily than with a flat flow extender. Variations in process conditions can cause undesired variations in the properties of the resulting semiconductor device; e.g., variations in the rate of deposition can cause variations in thickness of the deposited layers, which in turn can lead to non-uniform characteristics in the resulting devices.

The above specification and examples provide a complete description of the process and use of exemplary implementations of the invention. The above description provides specific implementations. It is to be understood that other implementations are contemplated and may be made without departing from the scope or spirit of the present disclosure. The above detailed description, therefore, is not to be taken in a limiting sense. While the present disclosure is not so limited, an appreciation of various aspects of the disclosure will be gained through a discussion of the examples provided.

Unless otherwise indicated, all numbers expressing feature sizes, amounts, and physical properties are to be understood as being modified by the term “about.” Accordingly, unless indicated to the contrary, the numerical parameters set forth are approximations that can vary depending upon the desired properties sought to be obtained by those skilled in the art utilizing the teachings disclosed herein.

As used herein, the singular forms “a”, “an”, and “the” encompass implementations having plural referents, unless the content clearly dictates otherwise. As used in this specification and the appended claims, the term “or” is generally employed in its sense including “and/or” unless the content clearly dictates otherwise.

Spatially related terms, including but not limited to, “lower”, “upper”, “beneath”, “below”, “above”, “on top”, etc., if used herein, are utilized for ease of description to describe spatial relationships of an element(s) to another. Such spatially related terms encompass different orientations of the device in addition to the particular orientations depicted in the figures and described herein. For example, if a structure depicted in the figures is turned over or flipped over, portions previously described as below or beneath other elements would then be above or over those other elements.

Since many implementations of the invention can be made without departing from the spirit and scope of the invention, the invention resides in the claims hereinafter appended. Furthermore, structural features of the different implementations may be combined in yet another implementation without departing from the recited claims.

What is claimed:

1. A wafer processing system comprising:
a chamber having a wall defining an interior volume, with a wafer carrier in the chamber, the wafer carrier having a peripheral edge and a top surface; and
a ring flow extender within the chamber around the wafer carrier, the ring flow extender having a top surface, a bottom surface opposite the top surface, an inner surface and an outer peripheral surface facing away from the wafer carrier extending from the top surface to the bottom surface, the outer peripheral having a radiused portion proximate the top surface defined by a radius no greater than 0.5 inch.

2. The wafer processing system of claim 1, wherein the radiused portion extends along the outer peripheral surface from the top surface no more than 0.5 inch.

3. The wafer processing system of claim 2, wherein the radiused portion extends along the outer peripheral surface from the top surface no more than 0.4 inch.

4. The wafer processing system of claim 1, wherein the radiused portion extends along the outer peripheral surface no more than 20% of the length of the outer peripheral surface.

5. The wafer processing system of claim 1, wherein a corner of the ring flow extender formed by the top surface and the inner surface is essentially level with the top surface of the wafer carrier.

6. The wafer processing system of claim 1, wherein the top surface of the ring flow extender is sloped upward and away from the top surface of the wafer carrier.

7. The wafer processing system of claim 6, wherein the top surface is at an angle between 60 to 75 degrees to vertical.

8. The wafer processing system of claim 1, wherein the radiused portion is defined by a radius no greater than 0.5 inch.

9. The wafer processing system of claim 8, wherein the radiused portion is defined by a radius of 0.1-0.5 inch.

10. The wafer processing system of claim 1, wherein the outer peripheral surface further has a lower portion extending from the radiused portion to the bottom surface.

11. The wafer processing system of claim 10, wherein the lower portion has a concave portion.

12. The wafer processing system of claim 10, wherein the lower portion and the radiused portion have a smooth juncture.

13. A ring flow extender for a wafer processing system, the ring flow extender comprising:
a top surface,
a bottom surface opposite the top surface,
an inner surface and
an outer peripheral surface having a radiused portion proximate the top surface and a lower portion proximate the bottom surface, the radiused portion defined by a radius no greater than 0.5 inch and extending from the top surface no more than 0.5 inch.

14. The ring flow extender of claim 13, wherein the radiused portion is defined by a radius no greater than 0.4 inch and extending from the top surface no more than 0.4 inch.

15. The ring flow extender of claim 13, wherein the radiused portion and the lower portion have a smooth juncture.

16. A method comprising:
positioning a wafer carrier and the ring flow extender according to claim 13 inside a reaction chamber so that the ring surrounds the carrier with a top surface of the carrier and the top surface of the ring facing in an upstream direction and being substantially planar with one another; and
directing one or more treatment gases in a downstream direction opposite to the upstream direction onto the top surfaces of the carrier while rotating the around an upstream-to-downstream axis of the carrier, so that treatment gases flow outwardly over the top surface of the carrier and the top surface of the ring.

17. A method of processing at least one wafer comprising:
positioning a wafer carrier supporting at least one wafer in a top surface thereof and a ring flow extender inside a reaction chamber, with the ring surrounding the wafer carrier with a top surface of the carrier and a top surface of the ring facing in an upstream direction and being substantially planar with one another, the ring having an outer peripheral surface facing away from the wafer carrier, the outer peripheral surface having a radiused portion proximate the top surface of the ring defined by a radius no greater than 0.5 inch; and
directing one or more treatment gases in a downstream direction opposite to the upstream direction onto the top surface of the carrier and the at least one wafer while rotating the carrier and the at least one wafer around an upstream-to-downstream axis of the carrier, so that treatment gases flow outwardly over the top surface of the carrier and over the top surface of the ring.

18. The method of claim 17 further comprising exhausting the one or more treatment gases from the chamber so that the gases flowing outwardly over the top surface of the ring pass downstream within a gap between the outer peripheral surface of the ring and a wall of the reaction chamber.

19. The method of claim 17 wherein the outer peripheral surface of the ring has a profile that inhibits accumulation of particles from the one or more treatment gases flowing within the gap onto the outer peripheral surface of the ring.
